(19) United States
(12) Patent Application Publication
(10) Pub. No.: US 2013/0248924 A1
(43) Pub. Date: Sep. 26, 2013

(54) SEMICONDUCTOR DEVICE

(71) Applicants: Tomoko MATSUDAI, Tokyo (JP); Tsuneo OGURA, Kanagawa-ken (JP); Hideaki NINOMIYA, Hyogo-ken (JP)

(72) Inventors: Tomoko MATSUDAI, Tokyo (JP); Tsuneo OGURA, Kanagawa-ken (JP); Hideaki NINOMIYA, Hyogo-ken (JP)

(73) Assignee: KABUSHIKI KAISHA TOSHIBA, Tokyo (JP)

(21) Appl. No.: 13/607,703

(22) Filed: Sep. 8, 2012

(30) Foreign Application Priority Data
Mar. 23, 2012 (JP) 2012-068090

(51) Int. Cl. H01L 29/739; H01L 21/336

(52) U.S. Cl. 257/139; 257/330; 257/E29.197; 257/E21.41

(57) ABSTRACT

A semiconductor device includes a reverse-conducting insulated gate bipolar transistor (IGBT), wherein the thickness of the semiconductor layer underlying the diode region of the device is thinner than the thickness of the semiconductor layer underlying the IGBT portion of the device. In one aspect, the semiconductor layer is a continuous layer, and trenches defining the anodes in the diode region extend further inwardly of the semiconductor layer than does the base regions of the IGBT portion of the device.

### CROSS-REFERENCE TO RELATED APPLICATION

This application is based upon and claims the benefit of priority from Japanese Patent Application No. 2012-068090, filed Mar. 23, 2012; the entire contents of which are incorporated herein by reference.

### FIELD

Embodiments described herein relate to a semiconductor device.

### BACKGROUND

In the recent years, extensive development has been carried out on the RC-IGBT (Reverse-Conducting IGBT), which has an IGBT (Insulated Gate Bipolar Transistor) and diodes formed on the same substrate. However, the thickness of the substrate (base layer) appropriate for realizing the ideal characteristics for both the IGBT and the diodes is different for each element, and this is a problem for the RC-IGBT. For example, when a base layer with the thickness appropriate for the IGBT is adopted, the diode characteristics of the RC-IGBT are sacrificed. On the other hand, when a base layer having a thickness appropriate for diodes is adopted, the IGBT characteristics are sacrificed.

### DESCRIPTION OF THE DRAWINGS

FIG. 1 is a cross-sectional view illustrating the structure of a semiconductor device according to a first embodiment.

FIG. 2 is a cross-sectional view illustrating the structure of a semiconductor device in according to a second embodiment.

FIG. 3 is a cross-sectional view illustrating the structure of a semiconductor device in according to a third embodiment.

FIG. 4 is a cross-sectional view illustrating the structure of a semiconductor device in according to a fourth embodiment.

FIG. 5 is a cross-sectional view illustrating the structure of a semiconductor device in a modified example of the first embodiment.

FIG. 6 is a cross-sectional view illustrating the structure of a semiconductor device in a modified example of the second embodiment.

FIG. 7 is a cross-sectional view illustrating the structure of a semiconductor device in a modified example of the fourth embodiment.

### DETAILED DESCRIPTION

In general, embodiments will be explained with reference to the figures.

According to the embodiment, there is provided a semiconductor device with excellent characteristics for all of the different types of elements formed on the same substrate.

One embodiment provides a semiconductor device that has a first semiconductor layer of the first electroconductive type, with a first surface and a second surface located on the side opposite to the first surface, and a second semiconductor layer of the second electroconductive type as well as a third semiconductor layer of the first electroconductive type formed adjacent to the second surface side of the first semiconductor layer. In addition, the device also has a fourth semiconductor layer of the second electroconductive type formed at a position opposite to the second semiconductor layer on the first surface side of the first semiconductor layer, and a fifth semiconductor layer of the first electroconductive type formed on the surface of the fourth semiconductor layer. In addition, the device also has a sixth semiconductor layer of the second electroconductive type formed at a position opposite to the third semiconductor layer on the first surface side of the first semiconductor layer, and a gate electrode formed via a gate-insulating film in a first trench through the fourth semiconductor layer. The depth of the bottom surface of the sixth semiconductor layer is deeper than the depth of the bottom surface of the fourth semiconductor layer, and the distance between the bottom surface of the sixth semiconductor layer and the second surface of the first semiconductor layer is shorter than the distance between the bottom surface of the fourth semiconductor layer and the second surface of the first semiconductor layer.

### Embodiment 1

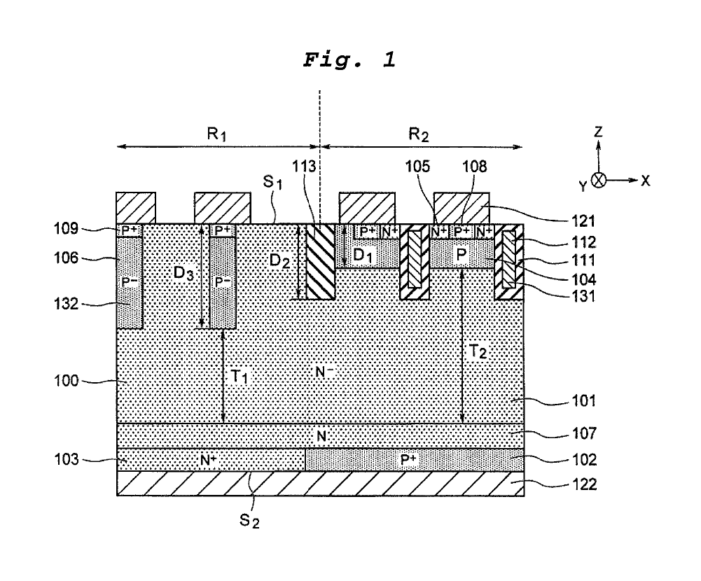

FIG. 1 is a cross-sectional view illustrating the structure of the semiconductor device in Embodiment 1.

The semiconductor substrate 100 in the semiconductor device shown in FIG. 1 has the following structure: an N-type first base layer 101 formed in a substrate 100, an N type buffer layer 107 at the base, or adjacent to the second principal surface S2 of the substrate 100, and a P+ type drain layer (collector layer) 102 provided over the buffer layer 107 and an N+ type cathode layer 103 as an example of the third semiconductor layer both formed in different discrete regions overlying the buffer layer 107. A second principal electrode overlies the P+ type drain layer (collector layer) 102 and N+ type cathode layer 103 on the second principal side S2 of the device.

In the IGBT region R2 of the device, on the opposed side of the first base layer 101 are provided a plurality of first trenches 131 extend inwardly of the first principal surface S1 of the substrate 100. A P type second base layer 104 as an example of the fourth semiconductor layer extends between adjacent trenches 131, and an N+ type source layer (emitter layer) 105 is formed over the second base layer 104 as an example of the fifth semiconductor layer, and a P+ type first contact layer 108 is formed adjacent to the is formed adjacent to source layer (s) 105 and generally centered over the second base layer 104. In the diode portion R1 of the device, a plurality of second trenches 132 extend inwardly of the First principal surface S1 of the substrate S1, and are filled with a P-type anode layer 106 as an example of the sixth semiconductor layer, and, a P+ type second contact layer 109 thereover, are provided.

The semiconductor device shown in FIG. 1 also has a gate-insulating film 111 lining the first trenches 131 and a gate electrode 112 extending within the trenches and isolated from the sidewalls thereof by the gate insulating film 111, and an element-isolating insulating film 113 filling the last trench 131 formed at the border between the diode region R1 and the IGBT region r2. A plurality of first principal electrodes 121 overlie, and are generally centered over, the first contact layers, and extend laterally to also overlie the adjacent source layer(s) 105. A second principal electrode 122 is formed continuously over both the P+ type drain layer (collector layer) 102 and N+ type cathode layer 103.

In this embodiment, the first and second electroconductive types represent the N type and P type, respectively. However, one may also adopt a scheme in which the first and second electroconductive types represent the P type and N type, respectively.

The semiconductor substrate 100 is, for example, a silicon substrate. Here, references S1 and S2 represent the outer surface (the first principal surface) and the back surface (the second principal surface) of the semiconductor substrate 100, respectively. In FIG. 1, the X-direction and Y-direction are perpendicular to each other and parallel with the principal surface of the semiconductor substrate 100, and the Z-direction is perpendicular to the principal surface of the semiconductor substrate 100. In addition to silicon, the material of the semiconductor substrate 100 may also be another homo-semiconductor or a compound semiconductor.

The first base layer 101 is a high-resistance layer in the semiconductor substrate 100. As shown in FIG. 1, the first base layer 101 is formed continuously in both the diode region R1 and the IGBT region R2.

The drain layer 102 and the cathode layer 103 are formed adjacent to each other on the back surface side of the first base layer 101. The drain layer 102 works as the drain and collector of the IGBT. On the other hand, the cathode layer 103 works as the cathode of the diode. As shown in FIG. 1, the drain layer 102 is formed in the IGBT region R2, and the cathode layer 103 is formed in the diode region R1.

The second base layer 104 is formed at a position opposite to the drain layer 102 on the first principal surface side S1 of the first base layer 101 (that is, it is formed at a position superposed with the drain layer 102 on the plane view) at a location intermediate of the first trenches 131. The source layer 105 is formed on the outer, first principal surface S1 side of the second base layer 104. In the diode region R1 of the device, the anode layer 106 is formed at a position opposed to the cathode layer 103 on the first principal surface S1 side of the first base layer 101 (that is, it is formed at a position superposed with the cathode layer 103 on the plane view), in the second trenches 132. The source layer 105 works as the source and emitter of the IGBT. On the other hand, the anode layer 106 works as the anode of the diode.

The buffer layer 107 is provided between the first base layer 101 and the drain layer 102 as well as the cathode layer 103. The buffer layer 107 works to limit the extension of the depletion layer from the second base layer 104 or the anode layer 106 towards the drain layer 102.

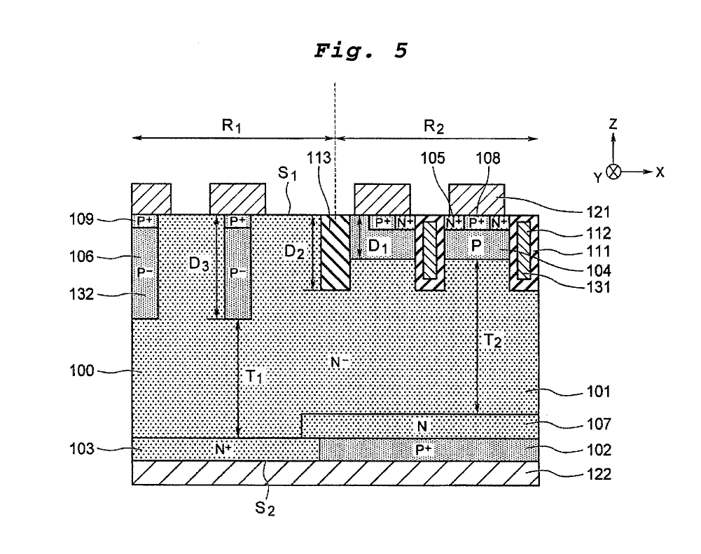

FIG. 5 is a cross-sectional view illustrating the structure of the semiconductor device in a modified example of Embodiment 1. Here, the buffer layer 107 may extends between the first base layer 101 and the drain layer 102, but, only partially between the first base layer 101 and the cathode layer 103 such that the buffer layer terminates before being interposed between ant of second trenches 132 and the cathode layer 103. The buffer layer 107 shown in FIG. 5 is an example of the eighth semiconductor layer.

In the following, with reference to FIG. 1, the semiconductor device of Embodiment 1 will be explained in more detail.

In the IGBT region R2 of the device, the first contact layer 108 (p+ doped film) is formed on the first principal surface S1 side of the second base layer 104, generally centered over the second base layer and adjacent to the source layer 105. The first contact layer 108 is used for making contact with the first principal electrode 121 in the IGBT region R2.

In the diode region R1 of the device, the second contact layer 109 is formed on the outer surface of the anode layer 106. The second contact layer 109 is formed for making contact with the first principal electrode 121 in the diode region R1.

The gate electrode 112 is formed over the gate-insulating film 111 in the first trench 131. An element-isolating insulating film 113 is formed in the first trench 131, which straddles or forms the boundary between the diode region R1 and the IGBT region R2 of the device. For example, the gate-insulating film 111 and the gate electrode 112 are silicon oxide and polysilicon, respectively. The gate electrode 112 works as the gate of the IGBT. The element-isolating insulating film 113 in the last first trench 131 is an insulator, such as silicon oxide.

The semiconductor substrate 100 has first trenches 131 and second trenches 132 extending inwardly of the substrate 100 and first base layer 101 from the first principal surface S1 side thereof. The first trenches 131 extend past the depth of the second base layers 104 from the first principal surface S1, and terminate in a bottom surface which is positioned deeper in the first base layer than is the bottom surface of the second base layer 104. The second trenches 132 extend from the first principal surface S1 of the device into the first base layer 101, and terminate in a bottom surface at the same depth as, or deeper than the bottom surface of the first trench 131.

References D1, D2 and D3 in FIGS. 1 and 5 represent the depths as measured form the first principal surface S1 of the semiconductor substrate 100 to the bottom surfaces of the second base layer 104, first trench 131, and second trench 132, respectively. In this embodiment, there is the following relationship between these depths: D1<D2≦D3.

In the present embodiment, the anode layer 106 is formed inside the second trench 132. As a result, the anode layer 106 has a bottom surface at the same depth as that of the bottom surface of the first trench 131, or deeper than that of the bottom surface of the first trench 131. In FIG. 1, the second trenches, and thus the depth of the anode layer 106, are deeper than the first trenches 131. In addition, the distance T1 between the bottom surface of the anode layer 106 and the lowermost surface of the first base layer 101 is shorter than the distance T2 between the bottom surface of the second base layer 104 and the back surface of the first base layer 101 (T1<T2). Here, distances T1 and T2 correspond to the effective thicknesses of the first base layer 101 in the diode region R1 and the IGBT region R2, respectively. For example, for the 1200V series semiconductor devices, the distances T1 and T2 are 100 μm and 130 μm, respectively.

For example, the anode layer 106 may be formed by depositing a P− type semiconductor layer by means of epitaxial growth, or the like, inside the second trench 132. For example, the second contact layer 109 may be formed by forming a P+ type semiconductor layer by means of epitaxial growth, ion implanting, or the like, on the outer surface of the P− type semiconductor layer.

On the first principal surface S1 of the semiconductor substrate 100, multiple first principal electrodes 121 are formed. The various first principal electrodes 121 are formed at positions overlying and in contact with the first contact layer 108 or the second contact layer 109.

On the second principal surface S2 of the semiconductor substrate 100, the second principal electrode 122 is shared by the diode region R1 and the IGBT region R2. The second principal electrode 122 is provided to contact both the drain layer 102 and the cathode layer 103.

As explained above, the semiconductor device shown in FIG. 1 has an RC-IGBT structure. When the semiconductor device shown in FIG. 1 is operating as an IGBT, the drain layer 102 is used as the drain and collector, and the source layer 105 is used as the source and emitter. On the other hand, when the semiconductor device shown in FIG. 1 is operating as a diode, the cathode layer 103 and anode layer 106 are used as cathode and anode, respectively.

### (1) Details of Distances T1 and T2

In the following, with reference to FIG. 1, the distances T1 and T2 will be explained in more detail.

As explained above, in the present embodiment, the depth D3 of the bottom surface of the anode layer 106 is selected to be deeper than the depth D1 of the bottom surface of the second base layer 104 (D3>D1). As a result, because the first base layer 101 is of a relatively uniform thickness, the distance T1 between the bottom surface of the anode layer 106 and the back surface of the first base layer 101 is also shorter than the distance T2 between the bottom surface of the second base layer 104 and the back surface of the first base layer 101 (T1<T2). That is, the effective thickness T1 of the first base layer 101 in the diode region R1 is thinner than the effective thickness T2 of the first base layer 101 in the IGBT region R2.

The effective thickness of the first base layer 101 appropriate for a diode is usually thinner than the effective thickness of the first base layer 101 appropriate for an IGBT. Consequently, in the present embodiment, by having the effective thickness T1 thinner than the effective thickness T2, it is possible to set the effective thicknesses T1 and T2 to be the thicknesses appropriate for the diode and IGBT, respectively in the same device. Consequently, in the present embodiment, it is possible to realize optimized characteristics for both the diode and the IGBT.

In the present embodiment, the anode layer 106 is formed in a differently sized second trench 132 than the size of the first trench 131. The first trench 131 is adopted for embedding the gate electrode 112, so that the depth D2 of the bottom surface of the first trench 131 is designed to be a depth appropriate for the gate electrode 112. Consequently, if the anode layer 106 is formed in a first trench 131, the depth D2 cannot be set to be the depth appropriate for the diode if all of the trenches have the same depth. This is undesirable.

On the other hand, in the present embodiment, the anode layer 106 is formed within the second trenches 132 which are deeper than the first trenches 131. Consequently, the depth D3 of the bottom surface of the second trench 132 can be set to be the depth appropriate for the diode. Usually, the depth D3 appropriate for the diode is deeper than the depth D2 appropriate for the gate electrode 112, because the thickness of the base region between the bottom of the anode layer 106 and the cathode layer 103 should be less than that between the second base layer 104 and the drain layer 102. Consequently, in the present embodiment, depth D3 is set to be deeper than the depth D2 (D3≧D2).

In the present embodiment, the thickness of the semiconductor substrate 100, and thus the first base layer 101, are preferably set at the thickness appropriate for the IGBT. This is because, if the thickness of the semiconductor substrate 100 and first base layer 101 are selected based on the requirements for the diode, the thickness of the semiconductor substrate 100 and first base layer is thinner than the effective thickness T2 appropriate for the IGBT, so that the effective thickness T2 cannot be set to be the thickness appropriate for the IGBT. On the other hand, if the thickness of the semiconductor substrate 100 is set to be the thickness appropriate for the IGBT, the effective thickness T1 appropriate for the diode can be realized by adjusting the depth D3.

In the present embodiment, it is preferred that the deeper the depth D3, the lower the impurity concentration in the anode layer 106. The reason is as follows: when the depth D3 is increased while the impurity concentration is kept constant, the total quantity (that is, the dosage) of the dopant required for the total volume of the anode layer 106 is increased, leading to deterioration in the recovery characteristics of the diode. In the present embodiment, the deeper the depth D3, the smaller the impurity concentration in the anode layer 106.

In addition, in the present embodiment, the second base layer 104 and the anode layer 106 are formed at different points in the process. Consequently, the concentration of impurities in the anode layer 106 may be different than the concentration of impurities in the second base layer 104.

### (2) Effects of Embodiment 1

Finally, the effects of Embodiment 1 are explained.

As explained above, in the present embodiment, the depth D3 of the bottom surface of the anode layer 106 is set to be deeper than the depth D1 of the bottom surface of the second base layer 104 (D3>D1), and thus where the first base layer 101 is of a uniform thickness, the distance T1 between the bottom surface of the anode layer 106 and the back surface of the first base layer 101 is shorter than the distance T2 between the bottom surface of the second base layer 104 and the base region of the first base layer 101 (T1<T2).

Consequently, in the present embodiment, the distances T1 and T2 are set at values appropriate for the diode and the IGBT, respectively, so that it is possible to ensure the ideal characteristics of both the diode and the IGBT.

Where the first base layer 101 is non-uniform, the depth of the trenches is not the optimizing factor, because the optimizing factor is the distance between the bottom of the trenches and the bottom or underside of the first base layer 101. Thus, the distance T1 shown in FIG. 5 is longer than the distance T1 shown in FIG. 1 by the thickness of the buffer layer 107. In FIG. 5, the depth D3 is set to be deeper than the sum of the depth D1 and the thickness of the buffer layer 107, and the distance T1 is set to be shorter than the distance T2.

### Embodiment 2

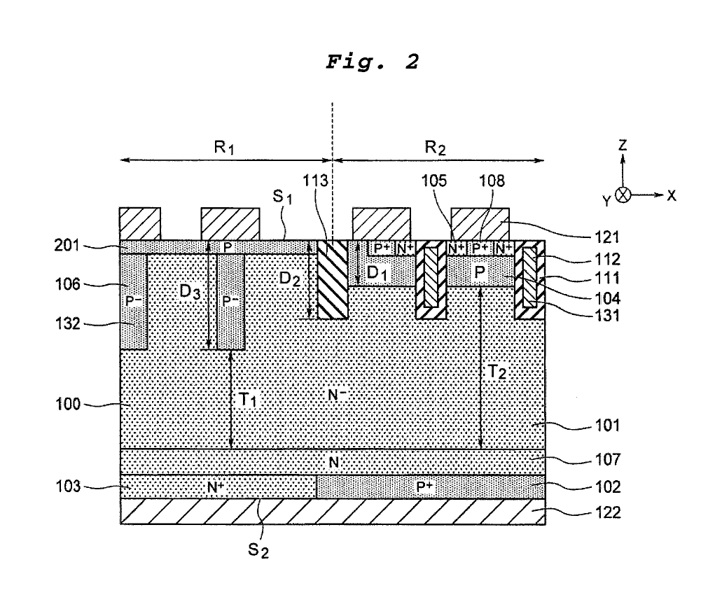

FIG. 2 is a cross-sectional view illustrating the structure of the semiconductor device in Embodiment 2.

In the present embodiment, the discrete second contact layers 109 overlying the anode layers 106 in FIG. 1 is replaced by a continuous second contact layer overlying multiple anode layers 106. Here, the second contact layer 201 is a P type layer with an impurity concentration that allows making ohmic contact with the first principal electrode 121. In the present embodiment, the impurity concentration of the second contact layer 201 is set to be lower than the impurity concentration of the first contact layer 108. The second contact layer 201 is an example of the seventh semiconductor layer.

As shown in FIG. 2, the area when each second contact layer 201 is set on the plane view is set larger than that of each anode layer 106 . In this structure, there is the advantage that the breakage voltage rating of the diode can be increased, and there is also an advantage that improvement is made on the margin for the position deviation when the first principal electrode 121 is formed on the second contact layer 201.

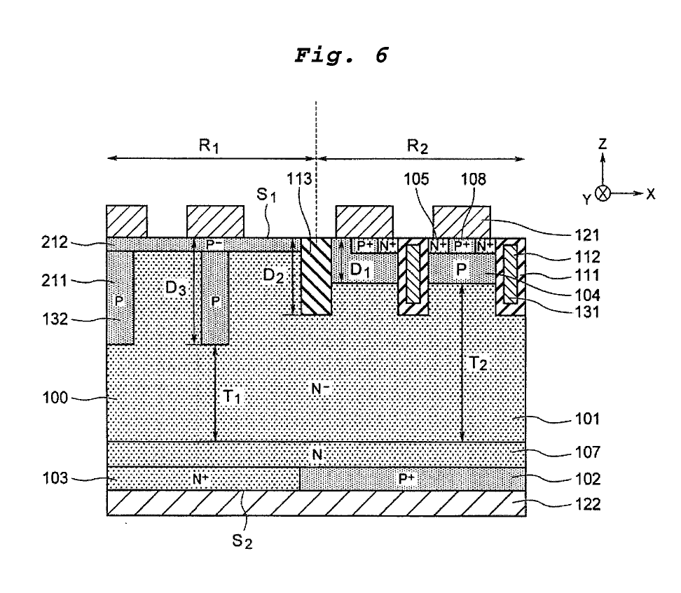

FIG. 6 is a cross-sectional view illustrating the structure of the semiconductor device in a modified example of Embodiment 2. In the modified embodiment, as shown in FIG. 6, a P− type anode layer 106 and the second contact layer 201 may be substituted for by the P type anode layer 211 and the P− type second contact layer 212, respectively. The anode layer 211 and the second contact layer 212 are examples of the sixth semiconductor layer and the seventh semiconductor layer, respectively.

In the diode region R1 shown in FIG. 6, the P type layer (second contact layer) 212 is formed on the entire surface of the first base layer 101, and a P type anode layer 211 fills the second trenches 132 extending into the first base layer 101. In this modified example, because the P type anode layer 211 with a high impurity concentration is provided, it is possible to design the anode layer 211 with a smaller impurity implanting quantity.

### Embodiment 3

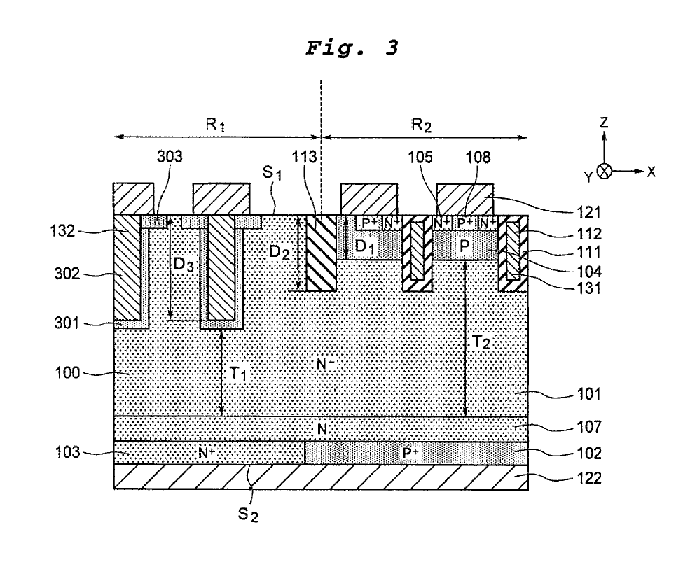

FIG. 3 is a cross-sectional view illustrating the structure of the semiconductor device in Embodiment 3.

In the present embodiment, the anode layer 106 shown in FIG. 1 is substituted for by the anode layer 301 shown in FIG. 3. On the outer side the second trench 132, an anode layer 301 is formed on the bottom surface and side surfaces of the second trenches 132. The anode layer 301 is a P− type layer just as with the anode layer 106, and it corresponds to an example of the sixth semiconductor layer.

An embedded semiconductor layer 302 fills the second trench 132. For example, the embedded semiconductor layer 302 is a polysilicon layer, and it corresponds to an example of the embedded layer. In the present embodiment, this embedded layer is formed of a semiconductor. However, it may also be made of a conductor. An example of such a conductor is W (tungsten), etc.

For example, the anode layer 301 and embedded semiconductor layer 302 may be formed as follows: after formation of the second trench 132, impurity ions are implanted in the bottom surface and side surface of the second trench 132, and, after ion implanting, a semiconductor material is then deposited to fill the interior of the second trench 132.

In the present embodiment, the second contact layer 109 shown in FIG. 1 is substituted for by the second contact layer 303 shown in FIG. 2. Here, the second contact layer 303 is a P type layer, and it is formed adjacent to the second trench 132 on the first principal surface S1 of the first base layer 101 and overlying the anode layer 310.

Embodiment 1 and Embodiment 3 are compared with each other, as follows.

As shown in FIG. 1, the anode layer 106 is formed inside the second trench 132.

On the other hand, as shown in FIG. 3, on the outer side the second trench 132 where the anode layer 301 is formed at a position in contact with the bottom surface and the side surface of the second trench 132, the total quantity of the impurity in the anode layer 106 may be smaller, corresponding to the proportion of the embedded semiconductor layer 302 in the second trench 132. Consequently, although the anode layer 106 is formed at a deep position, it is still possible to realize an anode layer 106 with a smaller impurity implanting quantity.

In the present embodiment, just as in Embodiment 1, the distance T1 between the bottom surface of the anode layer 301 and the back surface of the first base layer 101 is shorter than the distance T2 between the bottom surface of the second base layer 104 and the back surface of the first base layer 101 (see FIG. 3). Consequently, in the present embodiment, just as in Embodiment 1, distances T1 and T2 are set at values appropriate for the diode and the IGBT, respectively, and it is possible to realize ideal characteristics for both the diode and the IGBT.

### Embodiment 4

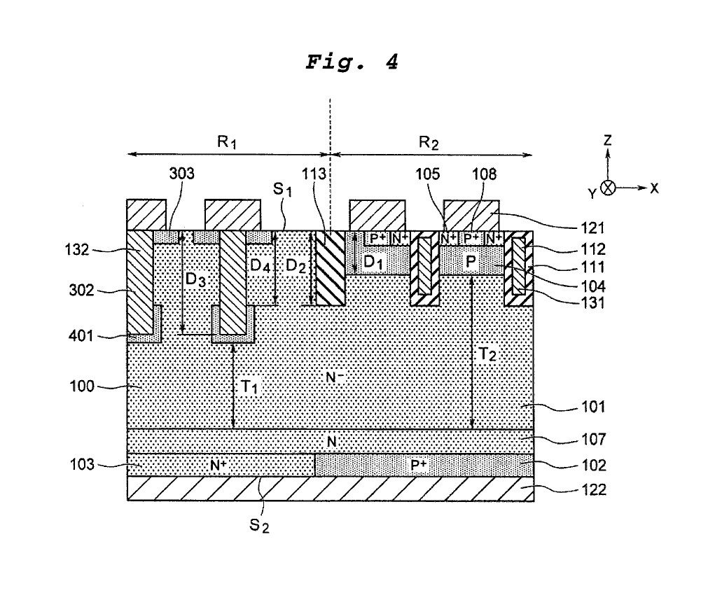

FIG. 4 is a cross-sectional view illustrating the structure of the semiconductor device in Embodiment 4.

In the present embodiment, the anode layer 301 shown in FIG. 3 is substituted for by the anode layer 401 shown in FIG. 4. Just as with the anode layer 301, the anode layer 401 is also formed on the outer side of the second trench 132 at the position in contact with the bottom surface and the side surface of the second trench 132. Here, the anode layer 401 is formed in contact with a portion of the side surface of the second trench 132, instead of with the entire side surface of the second trench 132. As a result, the side surface of the second trench 132 has a portion in contact with the anode layer 401 and a portion in contact with the first base layer 101. Just as with the anode layer 301, the anode layer 401 is also a P− type layer, and it corresponds to the sixth semiconductor layer.

In addition, because the anode layer 401 works as an anode, the anode layer 401 should be electrically connected to first principal electrode 121. Consequently, the semiconductor device of this embodiment has a region at a certain site in the diode region R1 where the anode layer 401 is formed on the entire side surface of the second trench 132. Here, the anode layer 401 may also be electrically connected to the first principal electrode 121 by another structure.

In the anode layer 401 in the present embodiment, it is possible to decrease the total quantity of the P type impurity to less than that of the anode layer 301 in Embodiment 3. In the present embodiment, as the depth D4 from the upper surface S1 of the semiconductor substrate 100 to the upper end of the anode layer 401 is increased, it is possible to have a smaller quantity of the P type impurity. Consequently, in order to decrease the impurity implanting quantity of the anode layer 401, it is preferred that the depth D4 be increased. In the present embodiment, for example, the depth D4 may be set to be equal to or greater than half of the depth D3 (D4≧D3/2).

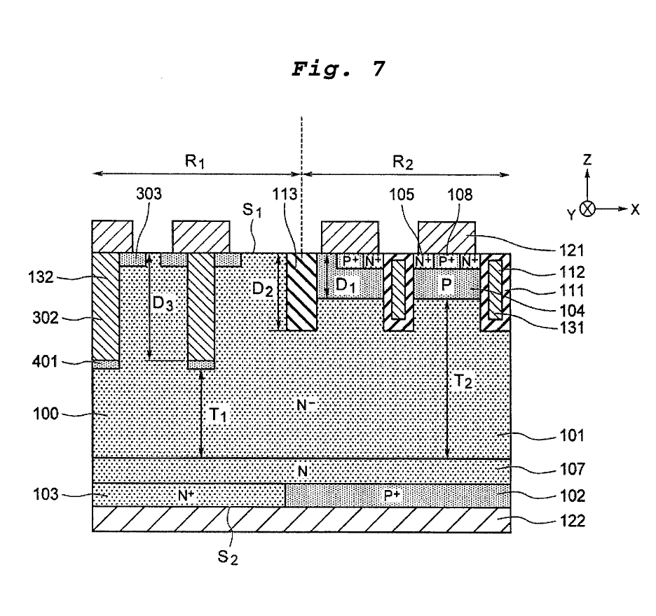

FIG. 7 is a cross-sectional view illustrating the structure of the semiconductor device in a modified example of Embodiment 4. As shown in FIG. 7, the anode layer 401 is only in contact with the bottom surface of the second trench 132, and it is not in contact with the side surface of the second trench 132. In the present embodiment, the structure shown in FIG. 7 may be adopted.

In the present embodiment, just as in Embodiment 3, the distance T1 between the bottom surface of the anode layer 401 and the back surface of the first base layer 101 is shorter than the distance T2 between the bottom surface of the second base layer 104 and the back surface of the first base layer 101 (see FIG. 4 and FIG. 7). Consequently, in the present embodiment, just as in Embodiment 3, by selecting distances T1 and T2 at values appropriate for the diode and the IGBT, respectively, it is possible to realize ideal characteristics for both the diode and the IGBT.

As shown in FIG. 1 through FIG. 7, the shape and configuration of the first principal electrode 121 can be selected as any desired shape and configuration. For example, in the case shown in FIG. 1, the first principal electrode 121 on the diode region R1 is arranged so that it is in contact with the first base layer 101 and the second contact layer 109. However, one may also adopt a scheme in which it contacts only the second contact layer 109. In addition, the multiple first principal electrodes 121 on the diode region R1 shown in FIG. 1 may be substituted by a single first principal electrode 121. In this case, the first principal electrode 121 contacts the first base layer 101 and multiple second contact layers 109, and it is arranged continuously on multiple second contact layers 109. These structures may also be adopted in FIG. 2 through FIG. 7.

Also, the boundary between the diode region R1 and the IGBT region R2 may be in agreement with the boundary between the drain layer 102 and the cathode layer 103, or it may be deviated from the latter boundary. In the latter case, the deviation quantity can be adjusted by means of designs of the boundary region, such as adjustment of the proportions of the diode region R1 and the IGBT region R2 in the RC-IGBT, or adjustment of the behavior of the carriers.

While certain embodiments have been described, these embodiments have been presented by way of example only, and are not intended to limit the scope of the embodiments. Indeed, the novel embodiments described herein may be embodied in a variety of other forms; furthermore, various omissions, substitutions, and changes in the form of the embodiments described herein may be made without departing from the spirit of the embodiments. The accompanying claims and their equivalents are intended to cover such forms or modifications as would fall within the scope and spirit of the embodiments.

What is claimed is:

1. A semiconductor device, comprising;
a substrate having a first base region, a first side and a second side;
a cathode region and a drain region disposed on a second side thereof;
a plurality of first trenches and a plurality of second trenches extending inwardly of the first base region from the first side thereof; the trenches terminating in a trench bottom; and
a second base layer interposed between the first trenches and extending inwardly of the first surface of the first base layer to a depth forming the bottom thereof,
wherein the thickness of the first base layer interposed between the bottom of a second trench and the second side of the first base layer is less than the thickness of the first base layer between the bottom of the second base layer and the second side of the first base layer.

2. The semiconductor device of claim 1, wherein the first trenches form a portion of an insulated gate bipolar transistor.

3. The semiconductor device of claim 1, wherein the second trenches form a portion of a diode structure, and the semiconductor device is a reverse-conducting insulated gate bipolar transistor.

4. The semiconductor device of claim 3, wherein the second base layer is a polysilicon layer.

5. The semiconductor device of claim 3, further including a buffer layer disposed between the drain layer and the first base layer.

6. The semiconductor device of claim 5, wherein the buffer layer further extends between the cathode layer and the first base layer.

7. The semiconductor device of claim 6, wherein a second electrode layer is disposed over the cathode layer and the drain layer.

8. The semiconductor device of claim 3, wherein at least one second trench includes an anode disposed therein.

9. The semiconductor device of claim 3, wherein at least one second trench includes an anode formed thereover, and a conductive plug extending inwardly of the second trench.

10. The semiconductor device of claim 9, wherein the conductive plug is poly silicon or tungsten.

11. The semiconductor device of claim 3, wherein the thickness of the first base layer is optimized for the performance of an insulated gate bipolar transistor.

12. A semiconductor device comprising:
a first semiconductor layer of the first electroconductive type with a first surface and a second surface located on the side opposite to the first surface;
a second semiconductor layer of the second electroconductive type as well as a third semiconductor layer of the first electroconductive type formed adjacent to the second surface side of the first semiconductor layer;
a fourth semiconductor layer of the second electroconductive type formed at a position opposite to the second semiconductor layer on the first surface side of the first semiconductor layer;
a fifth semiconductor layer of the first electroconductive type formed on the surface of the fourth semiconductor layer;
a sixth semiconductor layer of the second electroconductive type formed at a position opposite to the third semiconductor layer on the first surface side of the first semiconductor layer; and
a gate electrode formed via a gate-insulating film in a first trench through the fourth semiconductor layer, wherein
the depth of the bottom surface of the sixth semiconductor layer is deeper than the depth of the bottom surface of the fourth semiconductor layer;
the distance between the bottom surface of the sixth semiconductor layer and the second surface of the first semiconductor layer is shorter than the distance between the bottom surface of the fourth semiconductor layer and the second surface of the first semiconductor layer;
the depth of the bottom surface of the sixth semiconductor layer is identical to the depth of the bottom surface of the first trench, or deeper than the depth of the bottom surface of the first trench;
the sixth semiconductor layer is formed inside the second trench formed in the first semiconductor layer;
the device further comprises a seventh semiconductor layer of the second electroconductive type and formed on the outer surface of the sixth semiconductor layer and having an area on the plane view larger than that of the sixth semiconductor layer;
the second semiconductor layer is formed on the second surface side of the first semiconductor layer via the eighth semiconductor layer of the first electroconductive type;
the third semiconductor layer is formed on the second surface side of the first semiconductor layer so that it is in contact with the first semiconductor layer; and
the impurity concentration in the sixth semiconductor layer is different from the impurity concentration in the fourth semiconductor layer.

13. A semiconductor device comprising:
a first semiconductor layer of the first electroconductive type with a first surface and a second surface located on the side opposite to the first surface;
a second semiconductor layer of the second electroconductive type as well as a third semiconductor layer of the first electroconductive type formed adjacent to the second surface side of the first semiconductor layer;
a fourth semiconductor layer of the second electroconductive type formed at a position opposite to the second semiconductor layer on the first surface side of the first semiconductor layer;
a fifth semiconductor layer of the first electroconductive type formed on the surface of the fourth semiconductor layer;
a sixth semiconductor layer of the second electroconductive type formed at a position opposite to the third semiconductor layer on the first surface side of the first semiconductor layer; and
a gate electrode formed via a gate-insulating film in a first trench through the fourth semiconductor layer, wherein
the depth of the bottom surface of the sixth semiconductor layer is deeper than the depth of the bottom surface of the fourth semiconductor layer, and
the distance between the bottom surface of the sixth semiconductor layer and the second surface of the first semiconductor layer is shorter than the distance between the bottom surface of the fourth semiconductor layer and the second surface of the first semiconductor layer.

14. The semiconductor device according to claim 13, wherein
the depth of the bottom surface of the sixth semiconductor layer is identical to the depth of the bottom surface of the first trench, or deeper than the depth of the bottom surface of the first trench.

15. The semiconductor device according to claim 14, wherein
the sixth semiconductor layer is formed inside the second trench formed in the first semiconductor layer.

16. The semiconductor device according to claim 15, further comprising:
a seventh semiconductor layer of the second electroconductive type and formed on the outer surface of the sixth semiconductor layer and having an area on the plane view larger than that of the sixth semiconductor layer.

17. The semiconductor device according to claim 14, wherein
the sixth semiconductor layer is formed on the outer side the second trench formed in the first semiconductor layer and at a position in contact with the bottom surface or side surface of the second trench.

18. The semiconductor device according to claim 17, further comprising:
an embedded layer made of a semiconductor or a conductor and embedded inside the second trench.

19. The semiconductor device according to claim 18, wherein
at least a portion of the side surface of the second trench is in contact with the first semiconductor layer.

20. The semiconductor device according to claim 13, wherein
the second semiconductor layer is formed via an eighth semiconductor layer of the first electroconductive type on the second surface side of the first semiconductor layer;
the third semiconductor layer is formed on the second surface side of the first semiconductor layer so that it contacts the first semiconductor layer; and
the impurity concentration in the sixth semiconductor layer is different from the impurity concentration in the fourth semiconductor layer.
